(19) United States
(12) Patent Application Publication
(10) Pub. No.: US 2006/0284315 A1
(43) Pub. Date: Dec. 21, 2006

(54) Semiconductor device and circuit board

(75) Inventor: Naoyuki Suzuki, Sakai-shi (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/455,172

(22) Filed: Jun. 19, 2006

(30) Foreign Application Priority Data
Jun. 20, 2005 (JP) 2005-179190

(51) Int. Cl. H01L 23/48

(52) U.S. Cl. 257/737

(57) ABSTRACT

A semiconductor device 1 includes a silicon substrate 5, a semiconductor chip 2 placed on a surface S1 of the silicon substrate 5, a protruding electrode 6 (first protruding electrode) provided on a surface S2 of the semiconductor chip 2 opposite to the silicon substrate 5, and another protruding electrode 7 (second protruding electrode) provided on the surface S1 of the silicon substrate 5. Top portions of the protruding electrodes 6, 7 are of a generally same height from the surface S1 of the silicon substrate 5. In other words, the top portions of the protruding electrodes 6, 7 are flush on a plane parallel to the surface S1 of the silicon substrate 5.

This application is based on Japanese patent application No. 2005-179190, the content of which is incorporated hereinto by reference.

### BACKGROUND

1. Technical Field

The present invention relates to a semiconductor device and a circuit board.

2. Related Art

Semiconductor chips such as a diode, a transistor and a power MOSFET include those with a back electrode and one or more surface electrodes, the primary current path of which includes the back electrode. Referring to FIGS. 7 to 10, conventional semiconductor devices that include such type of semiconductor chip will be reviewed hereunder.

FIG. 7 is a cross-sectional view showing a conventional semiconductor device. In FIG. 7, a back electrode (not shown) of a semiconductor chip 102 and a lead frame 110 are mechanically and electrically connected, so that the semiconductor chip 102 is placed on the lead frame 110. A surface electrode (not shown) of the semiconductor chip 102 is connected to a lead 111 via a gold wire 112 by wire bonding. Further, the semiconductor chip 102, the lead frame 110 and the lead 111 are sealed in a sealing resin 113, exposing only an end portion of the lead 111.

FIG. 8 is a cross-sectional view showing a semiconductor device disclosed in Japanese Laid-open patent publication No. H11-177007 (patent document 1). In FIG. 8, the back electrode of the semiconductor chip 102 and the lead frame 110 are mechanically and electrically connected by a brazing material 116, so that the semiconductor chip 102 is placed on the lead frame 110. A protruding electrode 114 formed on a surface electrode 103 of the semiconductor chip 102 and the lead 111 are mechanically and electrically connected. Further, the semiconductor chip 102, the lead frame 110 and the lead 111 are sealed in the sealing resin 113, exposing only an end portion of the lead 111.

FIG. 9 is a cross-sectional view showing a semiconductor device disclosed in Japanese Laid-open patent publication No. 2000-243880 (patent document 2). In FIG. 9, the semiconductor chip 102 is placed on the lead frame 110 in a similar manner to FIG. 8. On each of the surface electrode 103 of the semiconductor chip 102 and the lead frame 110, a post electrode 115 is fixed by the brazing material 116. Further, the semiconductor chip 102, the lead frame 110 and the post electrode 115 are sealed in the sealing resin 113, exposing an end portion of the post electrode 115.

FIG. 10 is a cross-sectional view showing a semiconductor device disclosed in Japanese Laid-open patent publications No. 2000-277542 and No. 2005-051267 (patent documents 3 and 4). In FIG. 10, the semiconductor chip 102 is placed on the lead frame 110 in a similar manner to FIGS. 8 and 9. Here, an end portion of the lead frame 110 is bent at a right angle toward the side on which the semiconductor chip 102 is placed. On the surface electrode 103 of the semiconductor chip 102, the protruding electrode 114 is provided. Further, an edge 110a of the bent portion of the lead frame 110 and a top portion of the protruding electrode 114 are flush (on a plane parallel to the surface of the lead frame 110 on which the semiconductor chip 102 is placed), and both serve as an external electrode.

### SUMMARY OF THE INVENTION

The semiconductor devices shown in FIGS. 7 to 10, however, may incur stress strain because of a difference in thermal expansion coefficient between the semiconductor chip 102 predominantly constituted of silicon and the lead frame 110 of copper. Such stress strain provokes delamination between the semiconductor chip 102 and the lead frame 110, and breakdown of an adhesive combining the semiconductor chip 102 and the lead frame 110 (for example the brazing material 116 in FIGS. 8 to 10). Consequently, the delamination or the breakdown results in an increase in electrical resistance of the current path connecting the semiconductor chip 102 and the lead frame 110.

According to the present invention, there is provided a semiconductor device comprising a silicon substrate; a semiconductor chip placed on a surface of the silicon substrate; a first protruding electrode provided on a surface of the semiconductor chip opposite to the silicon substrate; a second protruding electrode provided on the surface of the silicon substrate; wherein a top portion of the first protruding electrode and that of the second protruding electrode are of a generally same height from the surface of the silicon substrate.

The semiconductor device thus constructed includes the silicon substrate for placing thereon the semiconductor chip. Such structure prevents emergence of stress strain originating from a difference in linear expansion coefficient between the semiconductor chip and the silicon substrate.

Thus, the present invention provides a semiconductor device that suppresses the stress strain between a semiconductor chip and a substrate carrying the semiconductor chip, and a circuit board provided with such semiconductor device.

### BRIEF DESCRIPTION OF THE DRAWINGS

The above and other objects, advantages and features of the present invention will be more apparent from the following description taken in conjunction with the accompanying drawings, in which:

FIG. 1 is a perspective view showing a semiconductor device according to an embodiment of the present invention;

FIG. 2 is a side view showing the semiconductor device according to the embodiment;

FIG. 3 is a side view showing a manufacturing process of the semiconductor device according to the embodiment;

FIGS. 4A to 4C are side views progressively showing a manufacturing process of the semiconductor device of FIGS. 1 and 2;

FIG. 5 is a side view showing a variation of the semiconductor device according to the embodiment;

FIG. 6 is a side view showing another variation of the semiconductor device according to the embodiment;

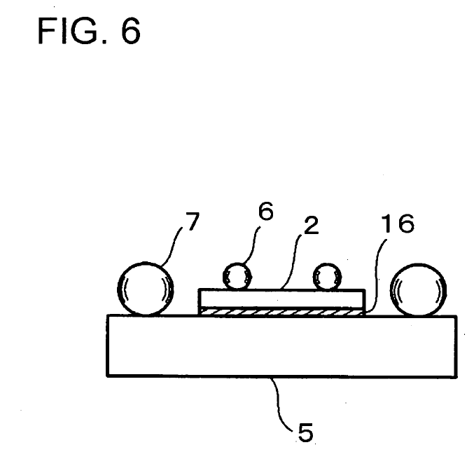

FIG. 7 is a cross-sectional view showing a conventional semiconductor device;

FIG. 8 is a cross-sectional view showing a semiconductor device disclosed in the patented document 1;

FIG. 9 is a cross-sectional view showing a semiconductor device disclosed in the patented document 2;

FIG. 10 is a cross-sectional view showing a semiconductor device disclosed in the patented documents 3 and 4; and

FIG. 11 is a side view showing a circuit board according to an embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, exemplary embodiments of a semiconductor device and a method of manufacturing the same according to the present invention will be described in details, referring to the accompanying drawings. In the drawings, same constituents are given the identical numerals, and duplicating description may be omitted where appropriate.

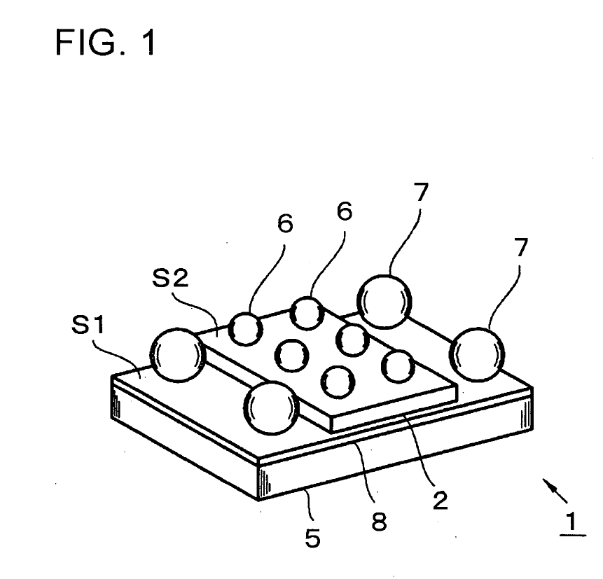

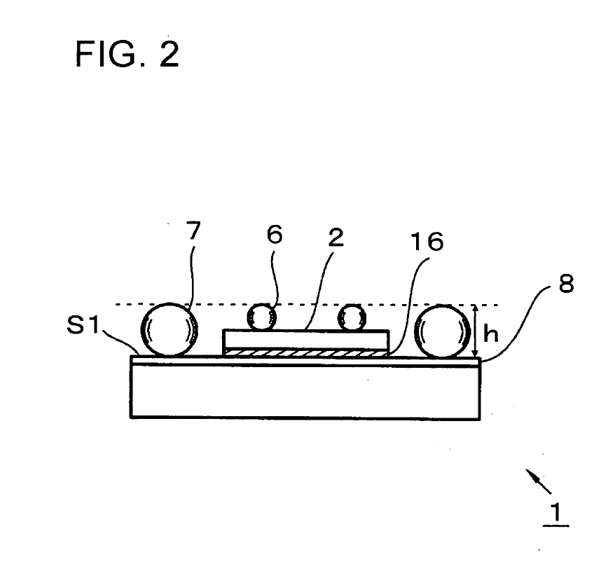

FIG. 1 is a perspective view showing a semiconductor device according to an embodiment of the present invention. FIG. 2 is a side view showing the semiconductor device according to the embodiment. The semiconductor device 1 includes a silicon substrate 5, a semiconductor chip 2 placed on a surface S1 of the silicon substrate 5, a protruding electrode 6 (first protruding electrode) provided on a surface S2 of the semiconductor chip 2 opposite to the silicon substrate 5, and another protruding electrode 7 (second protruding electrode) provided on the surface S1 of the silicon substrate 5.

The semiconductor chip 2 includes a surface electrode (not shown) formed on the surface S2 and a back electrode (not shown) formed on the opposite surface. The protruding electrode 6 is located on the surface electrode. The back electrode of the semiconductor chip 2 is mechanically and electrically connected to the silicon substrate 5 as shown in FIG. 2, by a brazing material 16. The brazing material 16 may be a cream solder or a conductive adhesive.

It is preferable that the semiconductor chip 2 and the silicon substrate 5 are constituted of a same material. In this embodiment, both the semiconductor chip 2 and the silicon substrate 5 are constituted of silicon. That is, the semiconductor substrate included in the semiconductor chip 2 is a silicon substrate. Over the surface S1 of the silicon substrate 5, a conductive layer 8, for example constituted of aluminum, is provided. The conductive layer 8 may be formed by a sputtering or a chemical vapor deposition (CVD) process. It is preferable to provide a coating such as NiAu plating in advance, on a region of the surface of the conductive layer 8 where the protruding electrode 7 is to be formed.

Top portions of the protruding electrodes 6, 7 are of the generally same height (indicated by h in FIG. 2) from the surface S1 of the silicon substrate 5. In other words, the top portions of the protruding electrodes 6, 7 are flush on a plane parallel to the surface S1 of the silicon substrate 5. The protruding electrode 7 located in a region other than where the semiconductor chip 2 is provided, on the surface S1 of the silicon substrate 5. When the semiconductor chip elaborated in the semiconductor chip 2 is a power MOSFET for example, the protruding electrode 6 is connected to the source and the gate thereof, and the protruding electrode 7 is connected to the drain via the silicon substrate 5. Preferably, the both protruding electrodes 6, 7 may be solder ball electrodes.

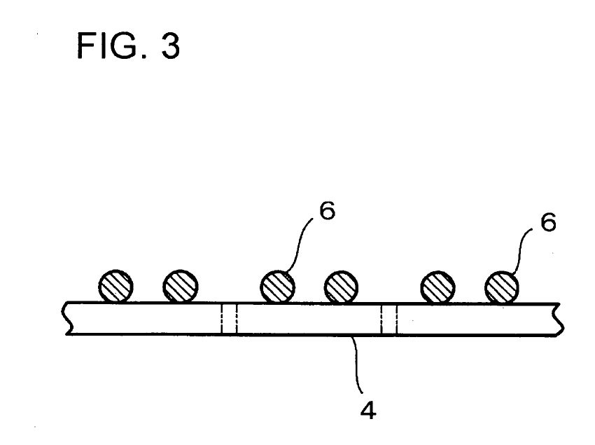

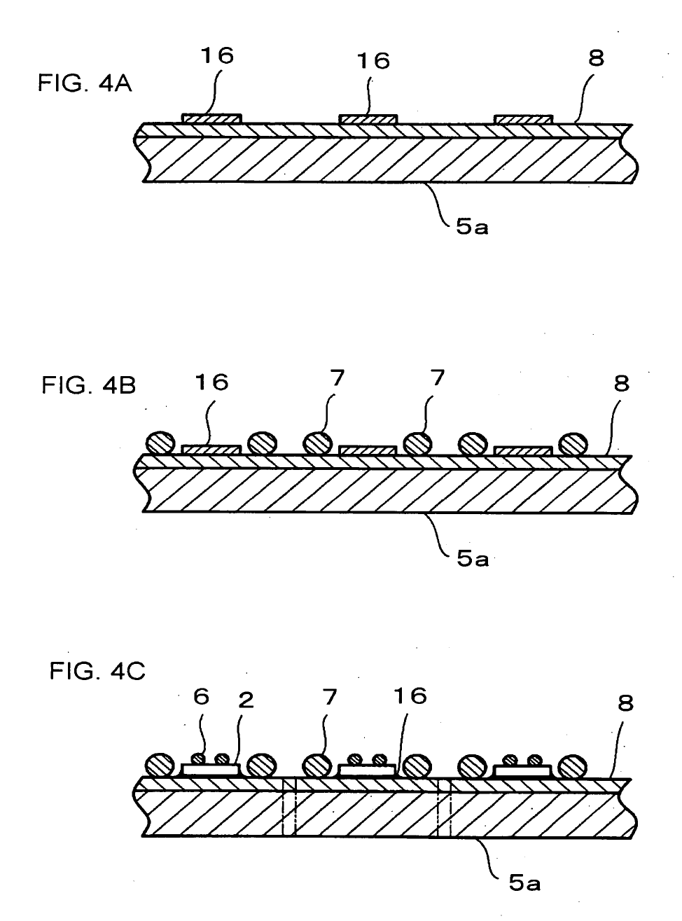

Referring to FIGS. 3 and 4A to 4C, a method of manufacturing the semiconductor device 1 will be described. Firstly, the protruding electrode 6 is formed on a chip-forming surface of a semiconductor wafer 4 (FIG. 3). Then the semiconductor wafer 4 is diced at positions indicated by dash-dot-dot lines in FIG. 3, to be split into the individual semiconductor chip 2. In FIG. 4A, the brazing material 16 is printed on positions where the semiconductor chips 2 are to be placed, on a front surface of the silicon substrate 5a where the conductive layer 8 is provided. In FIG. 4B, the protruding electrodes 7 are formed on predetermined positions on the conductive layer 8. Then the semiconductor chips 2 are fixed on the front surface of the silicon substrate 5a, by the brazing material 16 (FIG. 4C). Upon dicing the silicon substrate 5a at positions indicated by dash-dot-dot lines in FIG. 4C, the semiconductor device 1 is obtained.

Here, the protruding electrode 7 may be formed after placing the semiconductor chip 2 on the silicon substrate 5a. Also, the protruding electrodes 6, 7 may be both formed after placing the semiconductor chip 2 on the silicon substrate 5a. Such method allows continuously forming the protruding electrodes 6, 7, thereby making the manufacturing process simpler and easier. In particular, the protruding electrodes 6, 7 may be formed at a time, which further simplifies the manufacturing process.

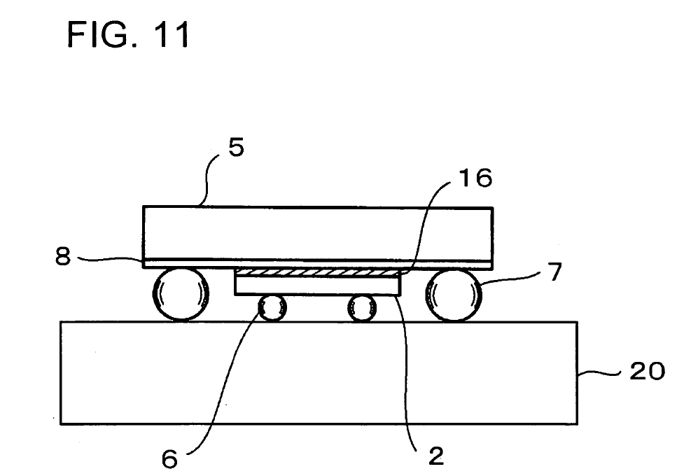

FIG. 11 is a side view showing a circuit board according to an embodiment of the present invention. The circuit board includes the semiconductor device 1, and a printed circuit board 20 connected to the protruding electrodes 6, 7 of the semiconductor device 1. In other words, the semiconductor device 1 is mounted on the printed circuit board 20 in a face-down orientation. On this circuit board, the protruding electrodes 6, 7 are exposed.

The foregoing embodiment provides the following advantages. The semiconductor device 1 includes the silicon substrate 5, for placing thereon the semiconductor chip 2. Such structure prevents emergence of stress strain originating from a difference in linear expansion coefficient between the semiconductor chip 2 and the silicon substrate 5.

Such stress strain may provoke delamination between the semiconductor chip 2 and the silicon substrate 5, and breakdown of the brazing material 16 combining the semiconductor chip 2 and the silicon substrate 5. Consequently, the delamination or the breakdown results in an increase in electrical resistance of the current path (for example the resistance of the back electrode of the semiconductor chip 2) connecting the semiconductor chip 2 and the silicon substrate 5. Suppressing such stress strain is, therefore, quite important.

In the semiconductor device 1, the semiconductor chip 2 is placed on the silicon substrate 5, instead of on a lead frame, which eliminates the need to provide a sealing resin. This prevents degradation in heat dissipation efficiency of the semiconductor device 1, which would otherwise be incurred by the sealing resin. Actually, the semiconductor device 1 is not provided with the sealing resin. Here, a resin may be provided on the surface S1 of the silicon substrate 5, for the purpose of reinforcing the semiconductor device 1. Even so, however, the back surface of the silicon substrate 5 (opposite to the surface S1) is not covered with the resin, and hence heat generated in the semiconductor chip 2 can be effectively dispersed through the side of the silicon substrate 5.

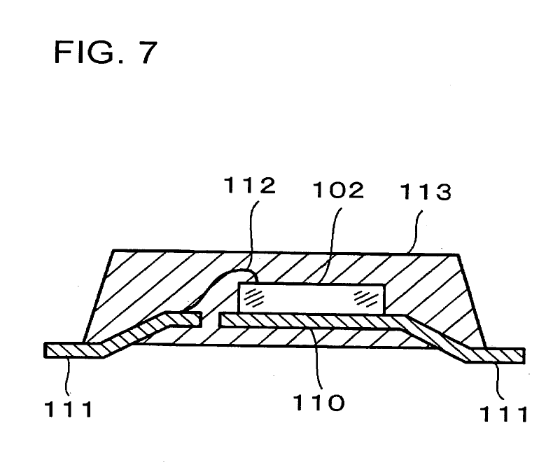

In the semiconductor devices shown in FIGS. 7 to 9, the semiconductor chip 102 and the lead frame 110 are covered with the sealing resin 113. Accordingly, those semiconductor devices have a room for improvement in the aspect of heat dissipation.

Further, the electrodes provided for the semiconductor chip 2 and the silicon substrate 5 are protruding electrodes (protruding electrodes 6, 7). Accordingly, when implementing the semiconductor device 1 on a substrate or the like, the electrodes can be connected to the substrate under the same condition. Therefore, the structure of the semiconductor device 1 facilitates the implementing process.

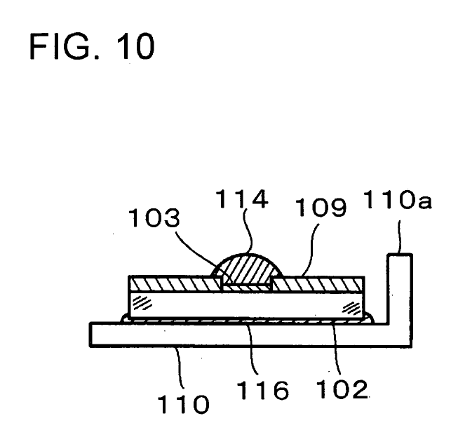

In contrast, the semiconductor device shown in FIG. 10 includes the electrodes of different natures, namely the protruding electrode 114 made of a solder bump or a solder ball and the edge 110a which is not provided with the solder. This makes it difficult to connect the protruding electrode 114 and the 110a to a printed circuit board or the like under the same condition, when implementing the semiconductor device on the board. Besides, an additional process of applying a cream solder to the edge 110a may have to be performed. The semiconductor device of FIG. 10, therefore, has a room for improvement in the aspect of implementation simpleness.

The application process of the cream solder to the edge 110a cannot be skipped even when, for example, all other components to be implemented (components to be mounted on the circuit board together with the semiconductor device 1) are semiconductor devices including solder ball electrodes such as a ball grid array (BGA) and a flip-chip (FC). Moreover, when the cream solder has to be applied to the circuit board such as a case that all other components to be implemented are of a lead type or a leadless chip carrier (LCC), or when the semiconductor devices are press-bonded to the circuit board by heat or pressure, it becomes difficult to unify the implementing conditions because of, for example, a difference in melting point between the protruding electrode 114 and the cream solder.

The protruding electrodes 6, 7 are the solder ball electrodes. Such structure permits skipping the cream solder application process to the circuit board, when all other components to be implemented are semiconductor devices including solder ball electrodes such as a BGA and a FC.

It is not, however, imperative that the protruding electrodes 6, 7 are the solder ball electrodes. The protruding electrode 6 may be a stud bump electrode, a post electrode, or a bump electrode. The stud bump electrode may be formed by bonding a fine metal wire. The post electrode may be formed by erecting a metal post on the semiconductor chip 2. The bump electrode may be formed by a plating process. Also, the protruding electrode 7 may be a post electrode or a bump electrode. The bump electrode corresponds to a post electrode in which the ratio of the height to the base is relatively small, and is in a shape, for instance, like a board, a disk or a hill.

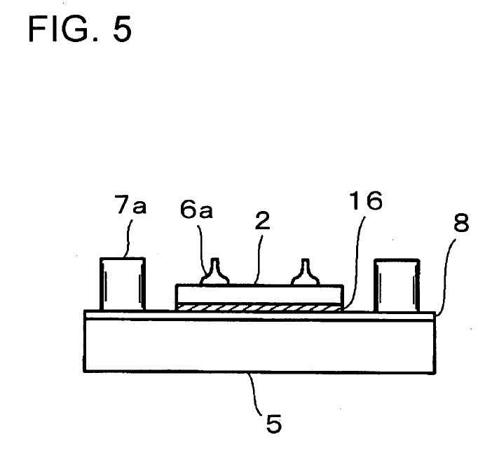

In FIG. 5 for example, a stud bump electrode 6a is provided as the first protruding electrode, and a post electrode 7a as the second protruding electrode. Such structure allows unifying the implementing process even when the cream solder has to be applied for implementing other components, or when heat or pressure is employed for press-bonding the semiconductor device on the circuit board. The stud bump electrode 6a is formed in the same way as ordinary wire bonding using ultrasonic waves or thermo compression bonding, where no brazing material is used. The post electrode 7a may be formed by a plating process without a brazing material used.

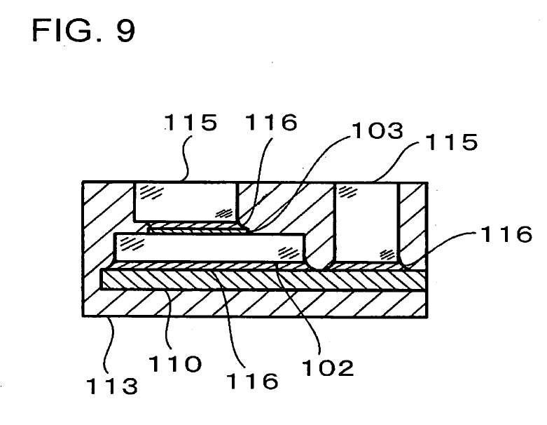

When the protruding electrodes 6, 7 are post electrodes, it is preferable to form the protruding electrodes 6, 7 directly on the semiconductor chip 2 and the silicon substrate 5 respectively. Such method enables more accurately forming the post electrodes at desired positions, than forming the post electrodes via the brazing material as shown in FIG. 9. For example, a plating process may be employed, for forming the post electrode directly on the semiconductor chip 2 and the silicon substrate 5.

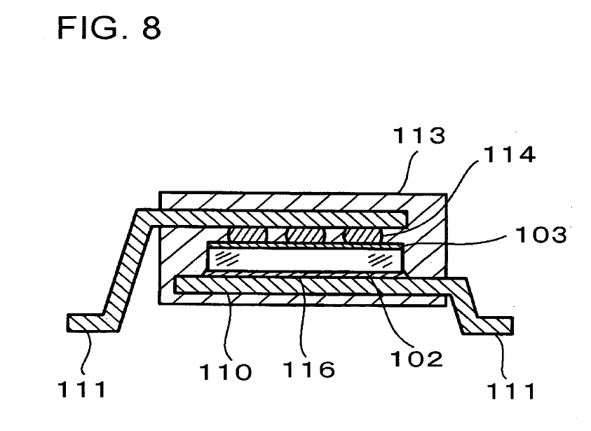

Further, since the semiconductor device 1 can be manufactured through a simpler process than the semiconductor devices shown in FIGS. 7 to 9, no increase in cost is incurred. Also, unlike the semiconductor devices shown in FIGS. 7 and 8, the lead is not sticking out of the sealing resin, which leads to reduced footprint of the device. Furthermore, all the external electrodes (protruding electrodes 6, 7) are constituted of a same metal material, and formed so that the top portions thereof become flush on the same plane. Such configuration allows implementing the semiconductor device 1 with other components under the same conditions.

The circuit board shown in FIG. 11 is provided with the semiconductor device 1 which is free from a sealing resin, and hence has excellent heat dissipation efficiency. In the circuit board, besides, the protruding electrodes 6, 7 are exposed. Such configuration provides even higher heat dissipation efficiency, compared with a case that a resin such as an underfill resin is loaded between the semiconductor device 1 and the printed circuit board 20.

Still further, since the electrodes provided for the semiconductor chip 2 and the silicon substrate 5 are both protruding electrodes (protruding electrodes 6, 7) as already stated, the semiconductor device 1 can be easily implemented on the printed circuit board 20. Thus, a circuit board easy to fabricate is provided.

The semiconductor device and the circuit board according to the present invention are not limited to the foregoing embodiment, but various modifications may be made. For example, a plurality of semiconductor chips 2 may be provided on the silicon substrate 5. In other words, a plurality of semiconductor chips may be loaded on the silicon substrate 5 if need be, so as to constitute a module.

It is apparent that the present invention is not limited to the above embodiment, and may be modified and changed without departing from the scope and spirit of the invention.

What is claimed is:

1. A semiconductor device comprising:
a silicon substrate;
a semiconductor chip placed on a surface of said silicon substrate;
a first protruding electrode provided on a surface of said semiconductor chip opposite to said silicon substrate;
a second protruding electrode provided on said surface of said silicon substrate;
wherein a top portion of said first protruding electrode and that of said second protruding electrode are of a generally same height from said surface of said silicon substrate.

2. The semiconductor device according to claim 1, wherein said semiconductor chip includes a back electrode connected to said silicon substrate.

3. The semiconductor device according to claim 1, wherein said first and second protruding electrodes are solder ball electrodes.

4. The semiconductor device according to claim 1, wherein said first and second protruding electrodes are post electrodes.

5. The semiconductor device according to claim 1, wherein said first and second protruding electrodes are provided without a brazing material on said semiconductor chip and said silicon substrate respectively.

6. The semiconductor device according to claim 1, wherein a plurality of said semiconductor chips are provided on said silicon substrate.

7. A circuit board comprising:
said semiconductor device according to claim 1; and
a printed circuit board connected to said first and second protruding electrodes.

8. The circuit board according to claim 7, wherein said first and second protruding electrodes are exposed.
